(19) United States
(12) Patent Application Publication
(10) Pub. No.: US 2020/0295150 A1
(43) Pub. Date: Sep. 17, 2020

(54) SEMICONDUCTOR DEVICE

(71) Applicants: Kabushiki Kaisha Toshiba, Minato-ku (JP); Toshiba Electronic Devices & Storage Corporation, Minato-ku (JP)

(72) Inventors: Tatsuya NISHIWAKI, Nonoichi (JP); Kentaro ICHINOSEKI, Nonoichi (JP); Hiroaki KATOU, Nonoichi (JP); Toshifumi NISHIGUCHI, Hakusan (JP)

(73) Assignees: Kabushiki Kaisha Toshiba, Minato-ku (JP); Toshiba Electronic Devices & Storage Corporation, Minato-ku (JP)

(21) Appl. No.: 16/529,368

(22) Filed: Aug. 1, 2019

(30) Foreign Application Priority Data
Mar. 14, 2019 (JP) 2019-047784

(51) Int. Cl. H01L 29/423; H01L 29/40; H01L 29/78; H01L 29/66

(52) U.S. Cl. CPC H01L 29/42376; H01L 29/4236; H01L 29/407; H01L 29/401; H01L 29/7813; H01L 29/66734; H01L 29/4238

(57) ABSTRACT

A semiconductor device of an embodiment includes: a first semiconductor layer having; a second semiconductor layer being provided on the first semiconductor layer; a third semiconductor layer being provided on the second semiconductor layer; a fourth semiconductor layer being provided on the third semiconductor layer; a field plate electrode provided in a trench via a first insulating film, the trench provided in the second semiconductor layer, the third semiconductor layer, and the fourth semiconductor layer; a first electrode provided in the trench to face the third semiconductor layer via a third insulating film; and a second insulating film provided in the trench to be interposed by the first electrodes and having a first portion, the first portion being interposed by lower ends of the first electrodes and having a width wider than a width of a second portion interposed by centers of the first electrodes.

### CROSS-REFERENCE TO RELATED APPLICATION

This application is based upon and claims the benefit of priority from Japanese Patent Application No. 2019-047784, filed on Mar. 14, 2019, the entire contents of which are incorporated herein by reference.

### FIELD

Embodiments described herein relate generally to a semiconductor device.

### BACKGROUND

A structure in which a field plate electrode connected to a source is buried in a striped trench is known as a structure of increasing a cell breakdown voltage and on-resistance of a power MOSFET having a trench-type field plate electrode structure.

However, even though the breakdown voltage in an element region is increased, there is a problem that a region between a gate electrode and the field plate electrode, which is insulated by an insulating film, is broken by a gate-source bias. In addition, there is a problem that parasitic capacitance between the gate electrode and the field plate electrode causes switching loss to increase.

### BRIEF DESCRIPTION OF THE DRAWINGS

FIG. 1 is a sectional view illustrating a semiconductor device 100 according to an embodiment;

FIG. 2 is a sectional view illustrating a semiconductor device 101 according to an embodiment;

FIG. 3 is a process diagram illustrating the semiconductor device 100 in an embodiment;

FIG. 4 is a process diagram illustrating the semiconductor device 100 in an embodiment;

FIG. 5 is a process diagram illustrating the semiconductor device 100 in an embodiment;

FIG. 6 is a process diagram illustrating the semiconductor device 100 in an embodiment;

FIG. 7 is a process diagram illustrating the semiconductor device 100 in an embodiment;

FIG. 8 is a process diagram illustrating the semiconductor device 100 in an embodiment;

FIG. 9 is a process diagram illustrating the semiconductor device 100 in an embodiment;

FIG. 10 is a process diagram illustrating the semiconductor device 100 in an embodiment;

FIG. 11 is a process diagram illustrating the semiconductor device 100 in an embodiment;

FIG. 12 is a process diagram illustrating the semiconductor device 100 in an embodiment;

FIG. 13 is a process diagram illustrating the semiconductor device 100 in an embodiment;

FIG. 14 is a sectional view illustrating a semiconductor device 200 according to an embodiment;

FIG. 15 is a sectional view illustrating the semiconductor device 200 in an embodiment;

FIG. 16 is a process diagram illustrating the semiconductor device 200 in an embodiment;

FIG. 17 is a process diagram illustrating the semiconductor device 200 in an embodiment;

FIG. 18 is a process diagram illustrating the semiconductor device 200 in an embodiment;

FIG. 19 is a process diagram illustrating the semiconductor device 200 in an embodiment; and

FIG. 20 is a sectional view illustrating a semiconductor device 201 in an embodiment.

### DETAILED DESCRIPTION

A semiconductor device of an embodiment includes: a first semiconductor layer having a first conductive type; a second semiconductor layer having the first conductive type and being provided on the first semiconductor layer; a third semiconductor layer having a second conductive type and being provided on the second semiconductor layer; a fourth semiconductor layer having the first conductive type and being provided on the third semiconductor layer; a field plate electrode provided in a trench via a first insulating film, the trench provided in the second semiconductor layer, the third semiconductor layer, and the fourth semiconductor layer; a first electrode provided in the trench to face the third semiconductor layer via a third insulating film; and a second insulating film provided in the trench to be interposed by the first electrodes and having a first portion, the first portion being interposed by lower ends of the first electrodes and having a width wider than a width of a second portion interposed by centers of the first electrodes.

Hereinafter, embodiments of the present disclosure will be described with reference to the drawings. In the drawings attached to this specification, for easy illustrations and understandings, the scale, the dimensional ratio of the length and the breadth, and the like are appropriately changed and exaggerated from those of the components in practice.

Hereinafter, the embodiments will be described with reference to the drawings. In the drawings, the same or similar parts are denoted by the same or similar reference signs.

In this specification, the same or similar members are denoted by the same reference signs and descriptions thereof may not be repeated.

In this specification, in order to indicate positional relations between the components and the like, the upward direction in the drawings is described as “upper”, and a downward direction in the drawings is described as “lower”. In this specification, “upper” and “lower” are necessarily terms indicating the relationship with the direction of gravity.

Further, it is assumed that terms of, for example, “parallel”, “orthogonal”, “identical”, and the like, which are used in this specification and are used for specifying the shape, geometrical conditions, and the degrees thereof, and values of the length, the angle, and the like are interpreted to include a range in which the similar function may be expected, without being bound by strict meanings.

In this specification, the expressions of n+, n, n−, p+, p, and p− indicate the relative degree of impurity concentration in each conductivity type. That is, n+ indicates the impurity concentration of an n-type impurity, which is relatively higher than the impurity concentration indicated by n. n− indicates the impurity concentration of the n-type impurity, which is relatively lower than the impurity concentration indicated by n. In addition, p+ indicates the impurity concentration of a p-type impurity, which is relatively higher than the impurity concentration indicated by p. p− indicates the impurity concentration of the p-type impurity, which is relatively lower than the impurity concentration indicated by p. n+ and n− may be simply described as the n-type, and p+ and p− may be simply described as the p-type.

In the following descriptions, descriptions will be made on the assumption that a first conductive type is the n-type, and a second conductive type is the p-type. Preferably, the first conductive type is the p-type, and the second conductive type is the n-type. The embodiments are embodied even if the first conductive type is set to the p-type, and the second conductive type is set to the n-type.

### First Embodiment

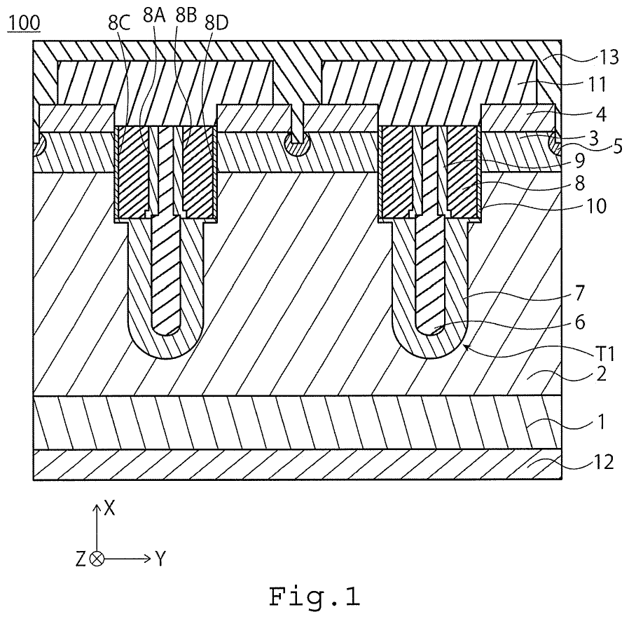

A first embodiment relates to a semiconductor device. FIG. 1 is a sectional view illustrating a semiconductor device 100 according to an embodiment.

A first direction X, a second direction Y, and a third direction Z intersect each other. The first direction X, the second direction Y, and the third direction Z are preferably orthogonal to each other.

The semiconductor device 100 is a power MOSFET, for example.

In FIG. 1, the semiconductor device 100 includes a first semiconductor layer (drain layer) 1 having a first conductive type, a second semiconductor layer (drift layer) 2, a third semiconductor layer (base layer) 3, a fourth semiconductor layer (source layer) 4, a field plate electrode 6, and a first electrode (gate electrode) 8. The second semiconductor layer 2 has the first conductive type and is provided on the first semiconductor layer 1. The third semiconductor layer 3 has a second conductive type and is provided on the second semiconductor layer 2. The fourth semiconductor layer 4 has the first conductive type and is provided on the third semiconductor layer 3. The field plate electrode 6 extends from the fourth semiconductor layer 4 toward the second semiconductor layer 2 in the first direction X. The field plate electrode 6 is located on the first semiconductor layer 1 side in a trench T1 which is provided in the second semiconductor layer 2, the third semiconductor layer 3, and the fourth semiconductor layer 4 and has the bottom located in the second semiconductor layer 2. The field plate electrode 6 is provided via a first insulating film (FP insulating film) 7. The first electrode 8 is positioned on the fourth semiconductor layer 4 side in the trench T1, interposes a second insulating film (poly oxide film) 9, and is provided via a third insulating film (gate insulating film) 10 provided on the outer side of the trench T1.

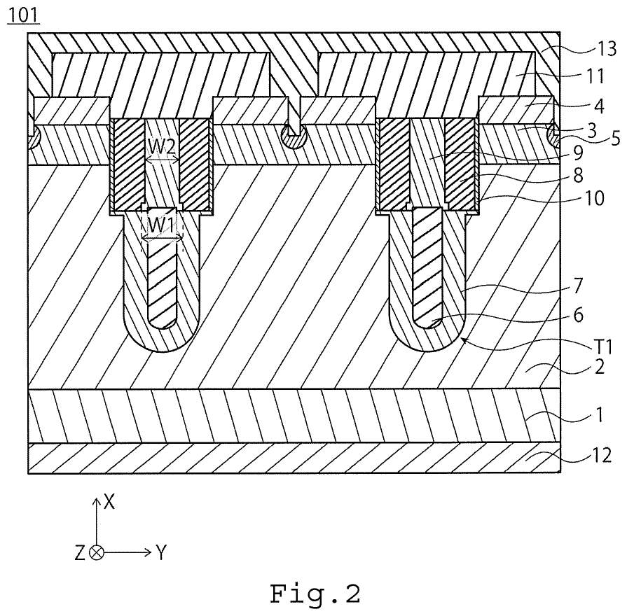

FIG. 2 is a sectional view illustrating a semiconductor device 101 in an embodiment. The semiconductor device 101 in FIG. 2 is a modification example of the semiconductor device 100. The upper portion of the field plate electrode 6 is interposed by the second insulating film 9 in the semiconductor device 100 in FIG. 1. However, the upper portion of the field plate electrode 6 is not interposed by the second insulating film 9 in the semiconductor device 101 in FIG. 2.

The first semiconductor layer (drain layer) 1 of the first conductive type is an n-type (n+ type) silicon layer, for example. The second semiconductor layer 2 is provided on one surface of the drain layer 1. For example, a second electrode (drain electrode) 12 is provided on a surface of the drain layer 1 on an opposite side of the surface on which the second semiconductor layer 4 is provided. For example, titanium (Ti), nickel (Ni), gold (Au), silver (Ag), or aluminum (Al) is used for the drain electrode 12.

The second semiconductor layer (drift layer) 2 of the first conductive type is an n-type (n− type) silicon layer, for example. The drift layer 2 is provided on the drain layer 1. The drain layer 1 and the drift layer 2 are stacked in the first direction X. The drift layer 2 has a trench (gate trench) T1. Any trench does not penetrate the drift layer 2. The bottom of the trench Ti is located in the drift layer 2.

The third semiconductor layer (base layer) 3 of the second conductive type is a p-type silicon layer, for example. The base layer 3 is provided on the drift layer 2. More specifically, the base layer 3 is selectively provided on the drift layer 2. The base layer 3 is located to interpose the trench Ti. The base layer 3 is, for example, a layer formed by implanting p-type dopant into the drift layer 2.

The fourth semiconductor layer (source layer) 4 of the first conductive type is an n+ type silicon layer provided on the base layer 3. The source layer 4 is provided on the base layer 3. More specifically, the source layer 4 is selectively provided on the base layer 3. The source layer 4 refers to, for example, a region formed by implanting n-type dopant into a portion of the base layer 3. The source layer 4 has a gap dividing the source layer in the second direction Y. The gap is filled with a source electrode 13.

The fifth semiconductor layer (base contact layer) 5 is a p+ type (second conductive type) silicon layer provided on the base layer 3. The base contact layer 5 is, for example, a layer formed by implanting p-type dopant into a portion of the base layer 3.

The field plate electrode 6, the first insulating film (FP insulating film) 7, the first electrode (gate electrode) 8, the second insulating film (poly oxide film) 9, and the third insulating film (gate insulating film) 10 are disposed in the trench Ti. The trench Ti extends from the source layer 4 toward the drain layer 2 in the first direction X, is provided in the drift layer 2, the base layer 3, and the source layer 3, and has the bottom located in the drift layer 2. An interlayer insulating film 11 may be disposed in the trench Ti on the upper side of the trench T1. The trench Ti penetrates the base layer 3 and the source layer 4 and reaches the drift layer 2. A side surface of the trench T1 is in contact with the drift layer 2, the base layer 3, and the source layer 4. The bottom surface of the trench T1 is in contact with the drift layer 2. In FIG. 1, the inside of the trench T1 is in contact with the first insulating film 7, the gate insulating film 10, and the interlayer insulating film 11. The trench T1 extends in a Z-direction perpendicular to an XY plane.

The field plate electrode 6 is an electrode provided to face the base layer 3 via the first insulating film (FP insulating film) 7. The field plate electrode 6 is located on the drain layer 1 side in the trench T1. Preferably, the field plate electrode 6 extends in the Z-direction. The field plate electrode 6 is electrically connected to the third electrode 13 on a not-illustrated surface, and thus has the same potential as that of the source electrode 12. The field plate electrode 6 is constituted by a conductive member of polysilicon, for example.

The field plate electrode 6 has a first portion having a thick film thickness on the bottom side of the trench T1. As in the semiconductor device 100 in FIG. 1, the field plate electrode 6 may have a second portion having a thin film thickness on the upper portion side of the trench T1. The film thickness of the field plate electrode 6 is a thickness in the second direction Y. As in the semiconductor device 101 in FIG. 2, the field plate electrode 6 may not have the second portion having a thin film thickness at the upper portion of the trench T1. Most or the entirety of the first portion of the field plate electrode 6 is interposed by the FP insulating film 7. The remaining portion of the first portion of the field plate electrode 6 may be interposed by the second insulating film 9. The second portion of the field plate electrode 6 is interposed or surrounded by the second insulating film 9. The lower portion of the field plate electrode 6 is surrounded by the FP insulating film 7. The upper portion of the field plate electrode 6 is interposed or surrounded by the second insulating film 9. The boundary between the first portion and the second portion is not clear, including a case where the thickness of the field plate electrode 6 obliquely changes. Although depending on a manufacturing process, for example, a form in which the film thickness of the second portion is too thin and a form in which the length of the second portion is short are included for the semiconductor device in the embodiment.

The first insulating film (FP insulating film) 7 is an insulating film disposed between the field plate electrode 6 and the drift layer 2. The inside of the FP insulating film 7 is in contact with the field plate electrode 6. The outside of the FP insulating film 7 is in contact with the drift layer 2. The FP insulating film 7 is along with the trench T1. The FP insulating film 7 is constituted by an insulating member of silicon oxide (SiO₂), for example.

The first electrode (gate electrode) 8 is an electrode provided via the third insulating film 10 provided in the trench T1. The gate electrode 8 is located on the source layer 4 side in the trench Ti in the first direction X. The gate electrodes 8 are provided in the trench T1 to interpose the second insulating film 9. The gate electrodes 8 interposing the second insulating film 9 are disposed in the second direction Y. The gate electrode 8 extends along the third insulating film 10 provided on the side surface of the trench T1, in the Z-direction. The gate electrode 8 is constituted by a conductive member of polysilicon, for example. The upper portion of the gate electrode 8 is in contact with the interlayer insulating film 11. The lower portion of the gate electrode 8 is in contact with the FP insulating film 7. The gate electrode 8 is interposed between the second insulating film 9 and the third insulating film 10 in the second direction Y.

The second insulating film (poly oxide film) 9 is an insulating film which is provided in the trench Ti to be interposed by the gate electrode 8. The poly oxide film 9 is located at the upper portion of the center of the trench T1. The side surface of the poly oxide film 9 is in contact with the gate electrode 8. The upper surface of the poly oxide film 9 is in contact with the interlayer insulating film 11. The lower surface of the poly oxide film 9 is in contact with the field plate electrode 6. In a case where the field plate electrode 6 has the second portion, the field plate electrode 6 is also located on the inner side of the poly oxide film 9. In FIG. 1, the second portion of the field plate electrode 6 penetrates the poly oxide film 9, and the upper surface of the second portion of the field plate electrode 6 is in contact with the interlayer insulating film 11. The poly oxide film 9 extends along the gate electrode 8 in the third direction Z. The poly oxide film 9 is constituted by an insulating member of silicon oxide (SiO₂), for example. The film thickness of the second insulating film (poly oxide film) is thicker than the film thickness of the third insulating film (gate insulating film).

In the embodiment, the boundary between the FP insulating film 7 and the poly oxide film 9 is determined as follows. An insulating film disposed closer to the bottom side of the trench Ti than the lower ends of the side surfaces 8A and 8B of the gate electrode 8 facing the center of the trench Ti (end portions of the side surfaces of the gate electrode 8 facing the center of the trench T1, on the drain layer 1 side in the first direction) is the FP insulating film 7. An insulating film which is provided from the lower ends of the side surfaces 8A and 8B of the gate electrode 8 facing the center of the trench T1 to the upper ends of the side surfaces of the gate electrode 8 facing the center of the trench T1 (end portions of the side surfaces of the gate electrode 8 facing the center of the trench T1, on a side of the side surface, which is opposite to the drain layer 1 side in the first direction) and is interposed by the side surfaces 8A and 8B of the gate electrode 8 facing the center of the trench T1 is set to the poly oxide film 9. All surfaces of the gate electrode 8 illustrated in FIGS. 1 and 2 are parallel to the first direction X or the second direction Y. However, even in a case where any surface of the gate electrode 8 is not parallel to the first direction X and the second direction Y, the boundary of the insulating film is determined by the similar method.

The third insulating film (gate insulating film) 10 is an insulating film disposed between the gate electrode 8 and the side surface of the trench T1. The gate insulating film 10 extends along the gate electrode 8 and the side surface of the trench T1 in the third direction Z. One side surface of the gate insulating film 10 is in contact with the gate electrode 8. The other side surface of the gate insulating film 10 is in contact with the drift layer 2, the base layer 3, and the source layer 4 as the side surface of the trench T1. The lower surface of the gate insulating film 10 is in contact with the FP insulating film 7. The upper surface of the gate insulating film 10 is in contact with the interlayer insulating film 11. The gate insulating film 10 is constituted by an insulating member of silicon oxide (SiO₂), for example.

In the embodiment, the boundary between the FP insulating film 7 and the gate insulating film 10 is determined as follows. An insulating film disposed closer to the bottom side of the trench Ti than the lower ends of the side surfaces 8C and 8D of the gate electrode 8 facing the side surface of the trench T1 (end portions of the side surfaces of the gate electrode 8 facing the side surface of the trench T1, on the drain layer 1 side in the first direction) is the FP insulating film 7. An insulating film which is provided from the lower ends of the side surfaces 8C and 8D of the gate electrode 8 facing the side surface of the trench T1 to the upper ends of the side surfaces 8C and 8D of the gate electrode 8 facing the side surface of the trench T1 (end portions of the side surfaces of the gate electrode 8 facing the side surface of the trench T1, on a side of the side surface, which is opposite to the drain layer 1 side in the first direction) and is interposed by the trench T1 is set to the poly oxide film 9. All surfaces of the gate electrode 8 illustrated in FIGS. 1 and 2 are parallel to the first direction X or the second direction Y. However, even in a case where any surface of the gate electrode 8 is not parallel to the first direction X and the second direction Y, the boundary of the insulating film is determined by the similar method.

The end portion of the gate electrode 8, which faces the field plate electrode 6 on the drain layer 1 side, is cut out. The notch-like shape is obtained by producing the semiconductor device with a manufacturing method according to the embodiment. In a case where the semiconductor device is produced by a manufacturing method of the semiconductor device in the related art, the end portion of the gate electrode, which faces the field plate electrode on the drain layer side, protrudes toward the field plate electrode.

Since the gate electrode 8 is cut out, the width W1 of the first portion of the poly oxide film 9, which is interposed by the lower ends of the gate electrodes 8, is wider than the width W2 of the second portion of the poly oxide film 9, which is interposed by the centers of the gate electrodes 8. In a case where the semiconductor device is produced by a manufacturing method of the semiconductor device in the related art, the end portion of the gate electrode, which faces the field plate electrode on the drain layer side, protrudes toward the field plate electrode. Thus, according to the semiconductor device in the related art, the width of the poly oxide film interposed by the lower ends of the gate electrodes is the narrowest among widths of the poly oxide film. Preferably, the center of the gate electrode 8 is at a position of the half the length of the gate electrode 8 in the second direction Y.

If the width W1 of the first portion of the poly oxide film 9 is wide, that is, if the notch-like shape is provided at the lower end of the gate electrode 9, it is possible to alleviate the concentration of an electric field at the lower end of the gate electrode 9. Thus, a breakdown voltage between the gate and the source of the semiconductor device 100 is increased. According to the configuration in the embodiment, regardless of whether the width of the trench T1 is wide or narrow, it is possible to alleviate the concentration of an electric field.

The width W1 of the first portion of the poly oxide film 9 is preferably equal to or more than 1.10 times and equal to or less than 3.00 times the width W2 of the second portion of the poly oxide film 9. If a difference between the width W1 of the first portion of the poly oxide film 9 and the width W2 of the second portion of the poly oxide film 9 is small, alleviation of the concentration of an electric field can be hardly expected. If the difference between the width W1 of the first portion of the poly oxide film 9 and the width W2 of the second portion of the poly oxide film 9 is too large, a place for forming the gate electrode is not provided. Thus, the width W1 of the first portion of the poly oxide film 9 is more preferably equal to or more than 1.20 times and equal to or less than 3.00 times the width W2 of the second portion of the poly oxide film 9.

Even in a case where the field plate electrode 6 extends up to the inside of the poly oxide film 9, the width of the poly oxide film 9 is obtained from an inter-interface distance between the poly oxide film 9 and the gate electrode 8.

The interlayer insulating film 11 is an insulating film disposed at the upper portion of the trench Ti and the upper portion of the source layer 4. The lower surface of the interlayer insulating film 11 in the trench T1 is in contact with the gate electrode 8, the poly oxide film 9, and the gate insulating film 10. The lower surface of the interlayer insulating film 11 outside of the trench T1 is in contact with the source layer 4. As in FIG. 1, the lower surface of the interlayer insulating film 11 in the trench T1 may be in contact with the upper portion of the second portion of the field plate electrode 6. The interlayer insulating film 11 is divided by a gap in the second direction Y, similar to the source layer 4. The gap is filled with the third electrode 13. The interlayer insulating film 11 is constituted by an insulating member of silicon oxide (SiO₂).

The third electrode 13 is a source electrode of the semiconductor device 100, which is connected to the source layer 4. The gap of the source layer 4 and the gap of the interlayer insulating film 11 are filled with the source electrode 13. The source electrode 13 is also provided on the source layer and the interlayer insulating film 11. For example, titanium (Ti), nickel (Ni), gold (Au), silver (Ag), aluminum (Al), titanium nitride (TiN), or tungsten (W) is used for the source electrode 13.

In other words, in the embodiment, the semiconductor device 100 includes the first semiconductor layer (drain layer) 1 having the first conductive type, the second semiconductor layer (drift layer) 2 which has the first conductive type and is provided on the first semiconductor layer 1, the third semiconductor layer (base layer) 3 which has the second conductive type and is provided on the second semiconductor layer 2, the fourth semiconductor layer (source layer) 4 which has the first conductive type and is provided on the third semiconductor layer 3, the field plate electrode 6 which is provided in the second semiconductor layer 2 via the first insulating film (FP insulating film) 7, the second insulating film (poly oxide film) 9 provided to be connected to the field plate electrode 6 from the fourth semiconductor layer 4, the first electrode (gate electrode) 8 interposing the second insulating film 9, and the third insulating film (gate insulating film) 10 interposing the first electrode 8.

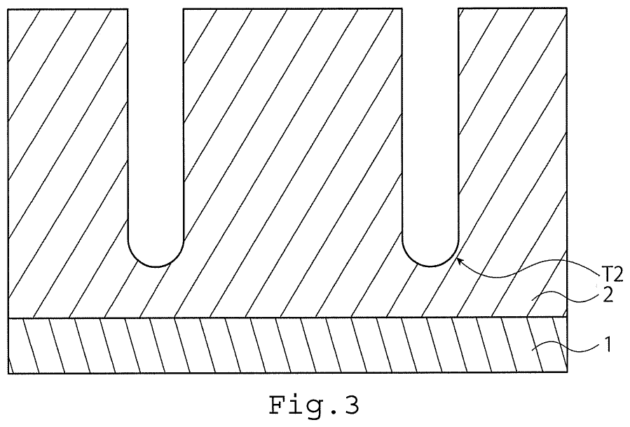

Next, the manufacturing method of the semiconductor device 100 according to the first embodiment will be described with the process diagrams in FIGS. 3 to 13. In the manufacturing method of the semiconductor device 100, for convenience, the first insulating film 7, the second insulating film 9, the third insulating film 10, and the interlayer insulating film 11 are described as an insulating film 14 without distinguishing from each other.

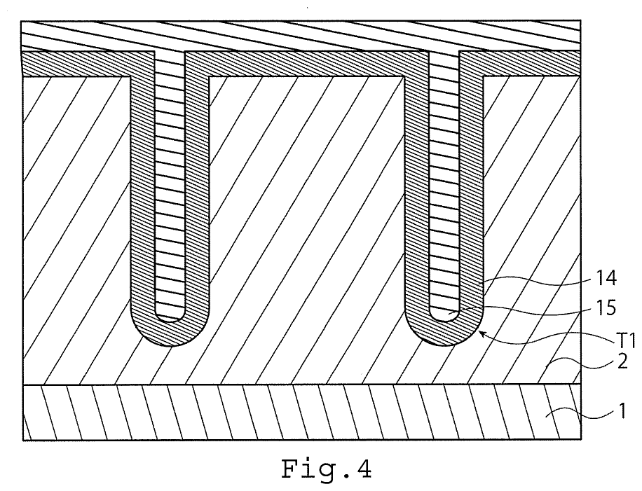

FIG. 3 is a process diagram of forming a trench T2 in a member obtained by forming the drift layer 2 on the drain layer 1. An oxide film 14 is formed on the surface of the member in the process diagram in FIG. 3 such that a space in the trench remains. Polysilicon 15 is formed on the oxide film 14 so as to bury the trench by the polysilicon 15, and thus a member in the process diagram illustrated in FIG. 4 is obtained. The formation of the oxide film 14 is not particularly limited, and, for example, thermal oxidation or CVD is used. Since a portion of the oxide film 14 is to serve as the FP insulating film 7, the oxide film 14 is formed to be thick.

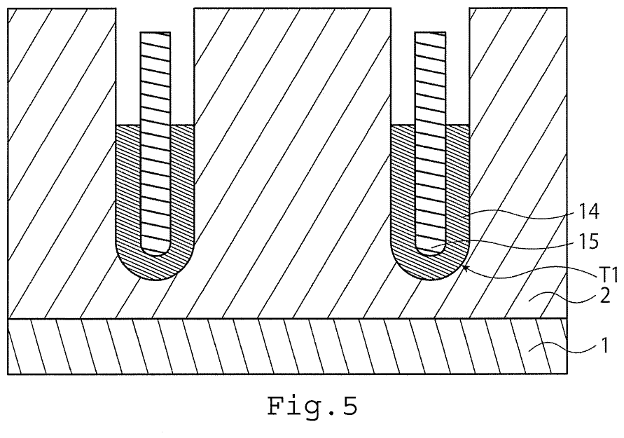

Then, the surface of the member in the process diagram in FIG. 4 is etched to remove the polysilicon 15 on the surface thereof and a portion of the polysilicon 15 in the trench. The oxide film 14 on the surface thereof and a portion of the oxide film 14 in the trench are removed by etching, and thereby a member in the process diagram in FIG. 5 is obtained. The larger amount of the oxide film 14 is removed such that the polysilicon 15 protrudes from the oxide film 14.

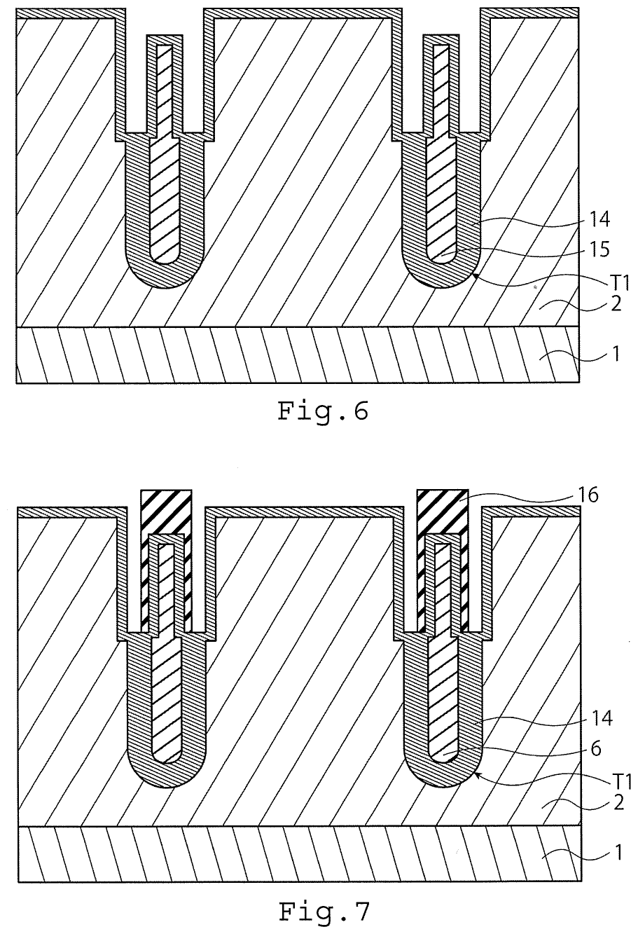

A member in the process diagram in FIG. 6 is obtained by oxidizing the drain layer 2 and the polysilicon 15 of the member in the process diagram in FIG. 5. with the oxidation, the surface of the drift layer 2 and a portion of the polysilicon 15 are oxidized, and thus the oxide film 14 is widened. In the process diagram in FIG. 6, a portion of the polysilicon 15, which corresponds to a portion protruding from the oxide film 14 in the process diagram in FIG. 4 is oxidized. However, the entirety of the polysilicon 15 corresponding to the portion protruding from the oxide film 14 is oxidized, and thus, finally, it is possible to obtain a structure like the semiconductor device 101 in FIG. 2. As an oxidation treatment, for example, thermal oxidation is performed. Silicon of the drift layer 2 or the polysilicon 15 is oxidized by performing a heat treatment, and thus silicon oxide is obtained. The remaining polysilicon 15 after the oxidation serves as the field plate electrode 6. With this process, the film thickness of the poly oxide film 9 is thicker than the film thickness of the gate insulating film 10.

Then, a resist 16 is formed to cover the insulating film 14 on the polysilicon 15 in the trench in a member in the process diagram of FIG. 6. A resist film is formed by sputtering and then is processed by lithography, and thereby the resist 16 covering the insulating film on the polysilicon 15 is formed as illustrated in the process diagram in FIG. 7.

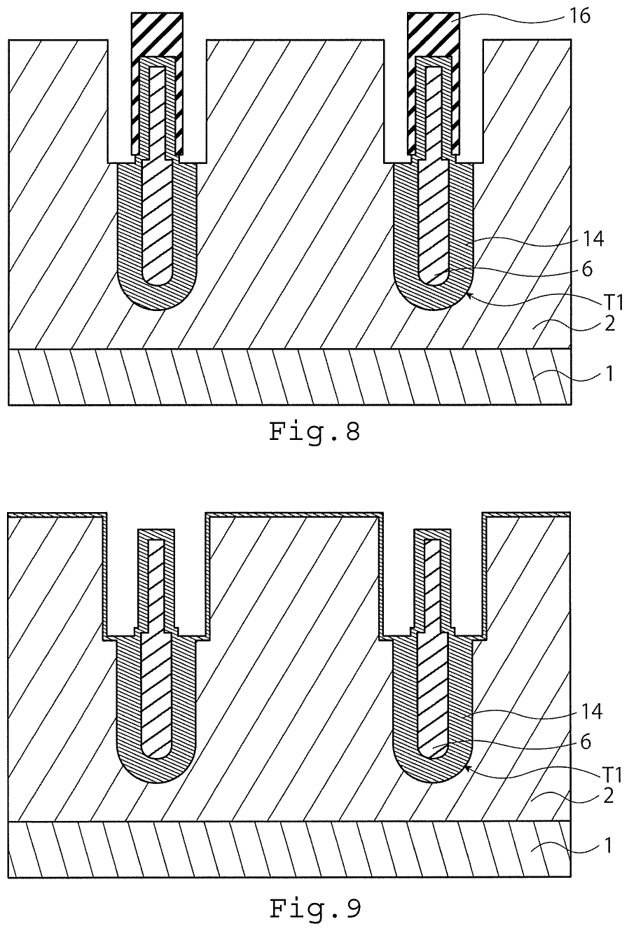

A portion of the oxide film 14 in a member in the process diagram in FIG. 7. The oxide film 14 at the deep portion of the trench and the oxide film 14 protected by the resist 16 remain. However, the oxide film on the surface of the trench and the surface of the drift layer 2 is removed. A portion of the side surface of the insulating film 14 under the resist 16 is also removed, and thus a member illustrated in the process diagram in FIG. 8 may be obtained.

Then, a member in the process diagram in FIG. 9 is obtained in a manner that the resist on a member in the process diagram in FIG. 8 is removed, and the oxide film 14 is formed on an exposed surface of the drift layer 2 in the trench. The oxide film 14 formed on the side surface of the trench in this process includes a portion which will serve as the gate insulating film 10 later. The thickness of the oxide film 14 in this process is adjusted to be equal to the designed thickness of the gate insulating film 10.

A step is provided in the insulating film 14 around the field plate electrode 6 in the member in the process diagram in FIG. 9. The step may have a rectangular shape as in FIG. 9 or may be a protrusion with rounded corners. With the step, a notch is formed at the lower end of the gate electrode 8 to be formed later. It is possible to alleviate the concentration of an electric field at the lower end at which the electric field easily concentrates, by the notch at the lower end of the gate electrode 8.

In the manufacturing method of the semiconductor device in the related art, the processes illustrated in the process diagram of FIGS. 6 to 8 are not performed. Thus, the film thickness of the second insulating film (poly oxide film) 9 is thin, the step is not formed, and the notch is not formed at the lower end of the gate electrode 8. The lower end of the gate electrode 8 is likely to protrude toward the field plate electrode 6. Since the film thickness of the second insulating film (poly oxide film) 9 is thick, and since the notch is formed at the lower end even though the lower end of the gate electrode 8 protrudes toward the field plate electrode 6, it is possible to alleviate the concentration of an electric field at the end of the gate electrode 8. Since the film thickness of the second insulating film (poly oxide film) between the gate electrode and the field plate electrode 6 is thicker than that in an example in the related art, parasitic capacitance between the gate electrode and the field plate electrode is reduced, and thus it is possible to reduce switching loss. The semiconductor device 100 in the embodiment has two excellent effects that the concentration of an electric field is alleviated, and the parasitic capacitance between the gate electrode and the field plate electrode is reduced in comparison to a semiconductor device manufactured by the manufacturing method in the related art.

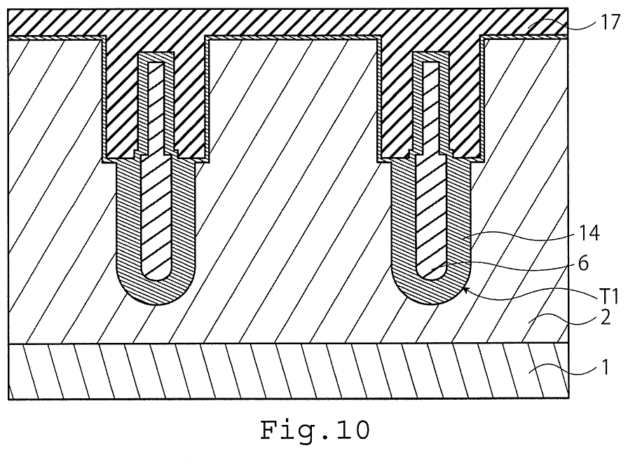

Then, a member in the process diagram in FIG. 10 is obtained by burying polysilicon 17 in the trench in the member in the process diagram in FIG. 9. The polysilicon 17 is formed on the insulating film 14. In the member in the process diagram in FIG. 10, a space in the trench in the member in the process diagram in FIG. 9 is filled with the polysilicon 17. The polysilicon 17 is also formed on the surface of the drift layer 2. The polysilicon 17 includes a portion which will be processed to serve as the gate electrode 8.

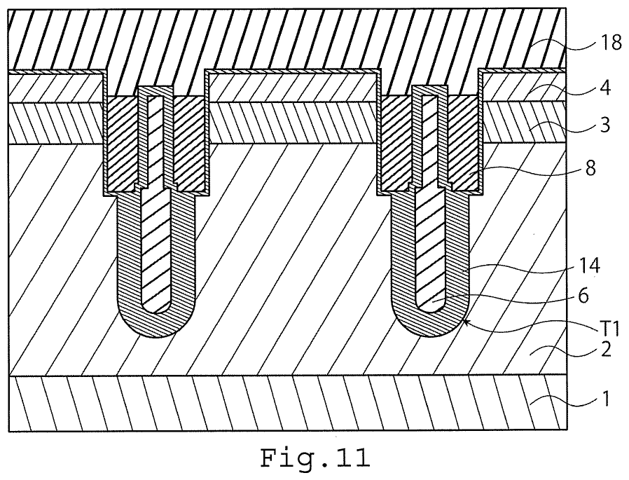

The polysilicon 17 of the member in the process diagram in FIG. 10 is processed by recess etching to be the gate electrode 8. Then, an insulating film 18 to serve as the interlayer insulating film 11 is formed on the insulating film 14 and the gate electrode 8 so as to obtain a member in the process diagram in FIG. 11. The insulating film is formed by CVD or the like.

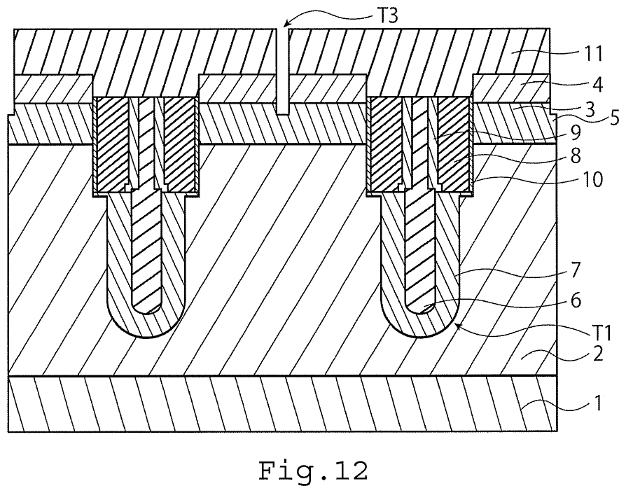

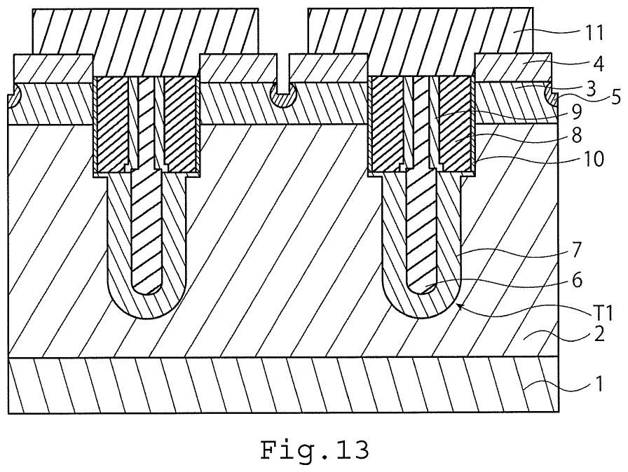

A member in which a trench T3 is formed, in the process diagram in FIG. 12 is obtained by etching the insulating film 18 of the member in the process diagram in FIG. 11 and etching the source layer 4 and the base layer 3. The trench T3 penetrates the interlayer insulating film 11 and the source layer 4 and has the bottom located in the base layer 3.

Then, the base contact layer 5 is formed in the base layer 3 by implanting p-type dopant into the trench of the member in the process diagram in FIG. 11, and the interlayer insulating film 11 is further etched so as to obtain a member in the process diagram in FIG. 13. The drain electrode 12 and the source electrode 13 are formed, and thus the semiconductor device 100 in FIG. 1 is obtained.

### Second Embodiment

A second embodiment relates to a semiconductor device. Some parts of the semiconductor device in the second embodiment are common with those of the semiconductor device in the first embodiment. Common descriptions in the first embodiment and the second embodiment will not be repeated.

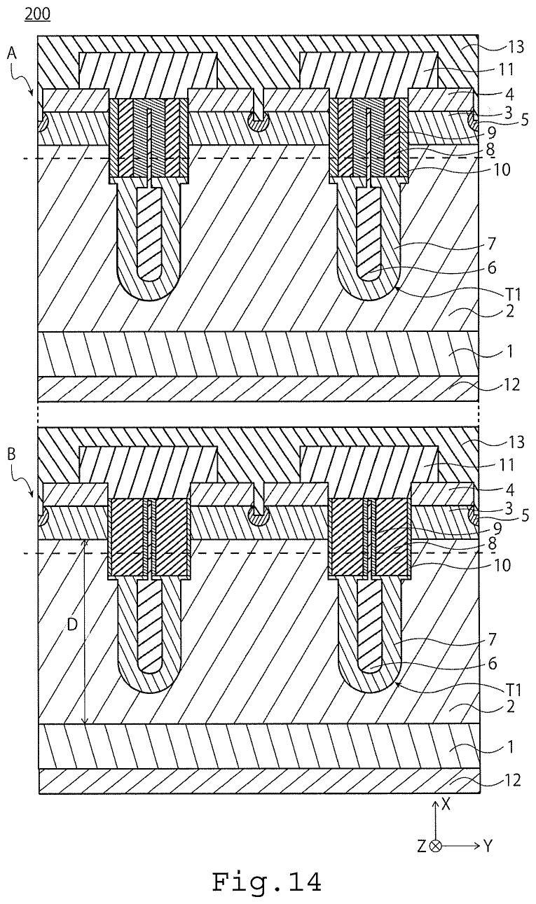

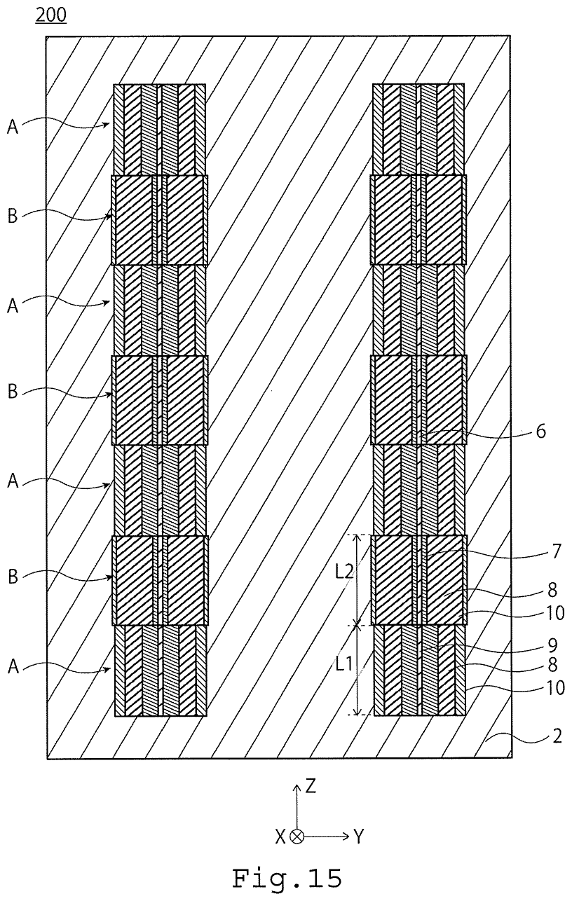

FIG. 14 is a sectional view illustrating a semiconductor device 200 in the second embodiment. The semiconductor device 200 includes a first semiconductor layer (drain layer) 1 having a first conductive type, a second semiconductor layer (drift layer) 2, a third semiconductor layer (base layer) 3, a fourth semiconductor layer (source layer) 4, a field plate electrode 6, and a first electrode (gate electrode) 8. The second semiconductor layer 2 has the first conductive type and is provided on the first semiconductor layer 1. The third semiconductor layer 3 has a second conductive type and is provided on the second semiconductor layer 2. The fourth semiconductor layer 4 has the first conductive type and is provided on the third semiconductor layer 3. The field plate electrode 6 extends from the fourth semiconductor layer 4 toward the second semiconductor layer 2 in the first direction X. The field plate electrode 6 is located on the first semiconductor layer 1 side in a trench Ti which is provided in the second semiconductor layer 2, the third semiconductor layer 3, and the fourth semiconductor layer 4 and has the bottom located in the second semiconductor layer 2. The field plate electrode 6 is provided via a first insulating film (FP insulating film) 7. The first electrode 8 is positioned on the fourth semiconductor layer 4 side in the trench T1, interposes a second insulating film (poly oxide film) 9, and is provided via a third insulating film (gate insulating film) 10 provided on the outer side of the trench T1.

In the semiconductor device 200, the thickness of the gate insulating film 10 in the Z-direction being a longitudinal direction of the trench Ti is different. More specifically, a first region A in which the gate insulating film 10 is thick and a second region B in which the gate insulating film 10 is thin are provided. The first region A and the second region B are regularly arranged. The first region A and the second region B are directly joined to each other. The longitudinal direction of the trench may be the longitudinal direction of the gate insulating film 10.

FIG. 15 is a sectional view illustrating the semiconductor device 200. The sectional view in FIG. 15 means a sectional view of the semiconductor device 200 taken along a broken line in FIG. 14. As illustrated in the sectional view in FIG. 15, the trench Ti extends in the Z-direction. The first region A and the second region B are alternately and regularly arranged in the longitudinal direction of the trench T1.

In the first region A, the capacitance around the channel is reduced because the gate insulating film 10 is thick. Since the gate insulating film 10 is thick, the gate (MOSFET) does not turn ON and function as a channel, or a threshold value is high and channel resistance is high. In the second region B, the gate insulating film 10 is thin, and thus the channel resistance is low. A proportion of the channel resistance to the total resistance is small (for example, 10% (over 100V class MOSFET)). Thus, an influence of the resistance of the semiconductor device is small. When the gate of the second region B whose the gate insulating film 10 is thin turns ON even though the gate insulating film 10 does not function as a channel in the first region A, electrons spread to the drift layer 2 in the first region A. Thus, the effect of reducing capacitance around the channel is exhibited larger. Accordingly, even though the gate insulating film 10 in the first region A does not function as a channel, an influence on the characteristics in the entirety of the semiconductor device is small.

If the thickness of the gate insulating film 10 in the first region A is too thick, it is required to increase the width of the trench as much as the thickness of the gate insulating film 10 in the first region A is thick. Thus, on-resistance increases. If the thickness of the gate insulating film 10 in the first region A is too thin, it is difficult to reduce the capacitance around the channel. Thus, the thickness of the gate insulating film 10 in the first region A in which the gate insulating film 10 is thick is preferably equal to or more than two times and equal to or less than ten times the thickness of the gate insulating film 10 in the second region B in which the gate insulating film 10 is thin.

If the proportion of the first region A increases and thus is too high, spreading electrons from the drift layer 2 in the second region B to the drift layer in the first region A has difficulty, and on-resistance increases. Thus, the length L1 of the gate insulating film 10 in the first region A in the longitudinal direction of the trench is preferably equal to or less than two times the thickness of the drift layer 2 in the first direction X, and more preferably equal to or more than 0.5 times and equal to or less than 2.0 times. If the proportion of the first region A with respect to the proportion of the second region B is reduced, and thus is too small, and if it is considered that the effect of reducing the capacitance around the channel is reduced, the length L1 of the gate insulating film 10 in the first region A in the longitudinal direction of the trench is preferably equal to or more than 0.5 times and equal to or less than 2.0 times the length L2 of the gate insulating film 10 in the second region B in the longitudinal direction of the trench.

In the first region A, the thickness (distance in the second direction Y) of the poly oxide film 9 increases, and thus it is possible to reduce the parasitic capacitance between the gate electrode 8 and the field plate electrode 6 electrically connected to the source electrode 13. From a viewpoint of reducing QGS in the entirety of the semiconductor device by reducing the parasitic capacitance in the first region A, the thickness of the poly oxide film 9 in the first region A is preferably thicker than the poly oxide film 9 in the second region B, and is more preferably equal to or more than 1.5 times and equal to or less than 4.0 times the thickness of the poly oxide film 9 in the second region B.

As described above, since the resistance slightly increases, but the capacitance is reduced, the on-resistance (Ron) xQ_{GS} and RonxQ_{GD} decrease, and thus the characteristics of the semiconductor device are improved.

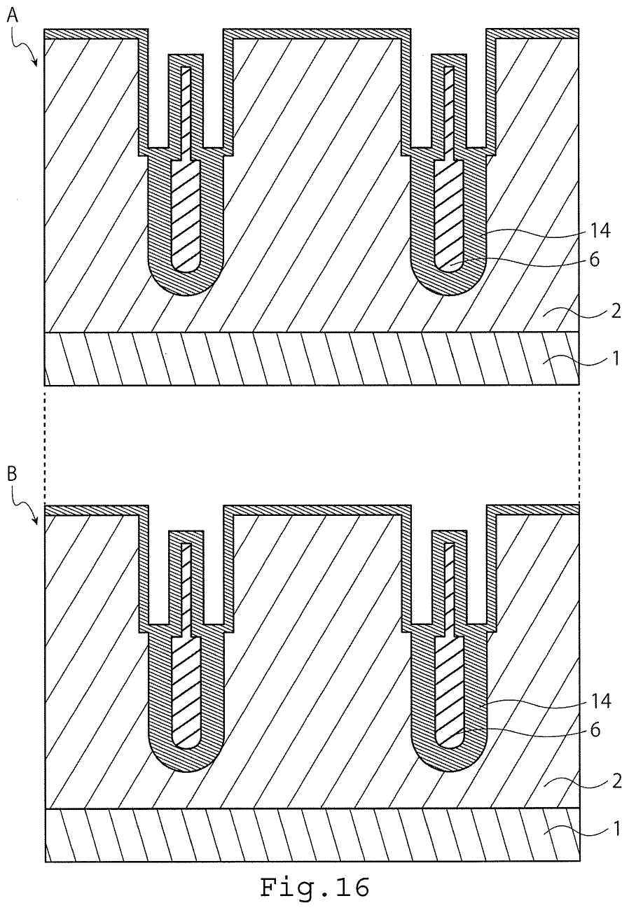

Next, the manufacturing method of the semiconductor device 200 according to the second embodiment will be described with the process diagrams in FIGS. 16 to 19. In the manufacturing method of the semiconductor device 200, for convenience, the first insulating film 7, the second insulating film 9, the third insulating film 10, and the interlayer insulating film 11 are also described as an insulating film 14 without distinguishing from each other.

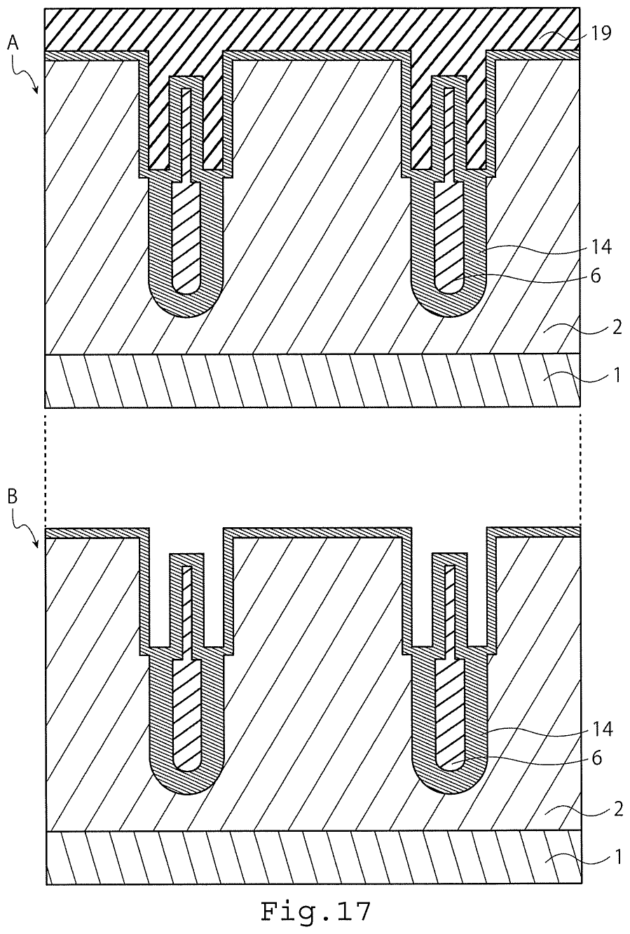

A member illustrated in the process diagram in FIG. 16 is obtained by the method illustrated in the process diagram of FIG. 6 in the first embodiment. A resist 19 is formed in the first region A, and thus a member illustrated in the process diagram in FIG. 17 is obtained. As illustrated in the process diagram in FIG. 17, the resist 19 is not formed in the second region B.

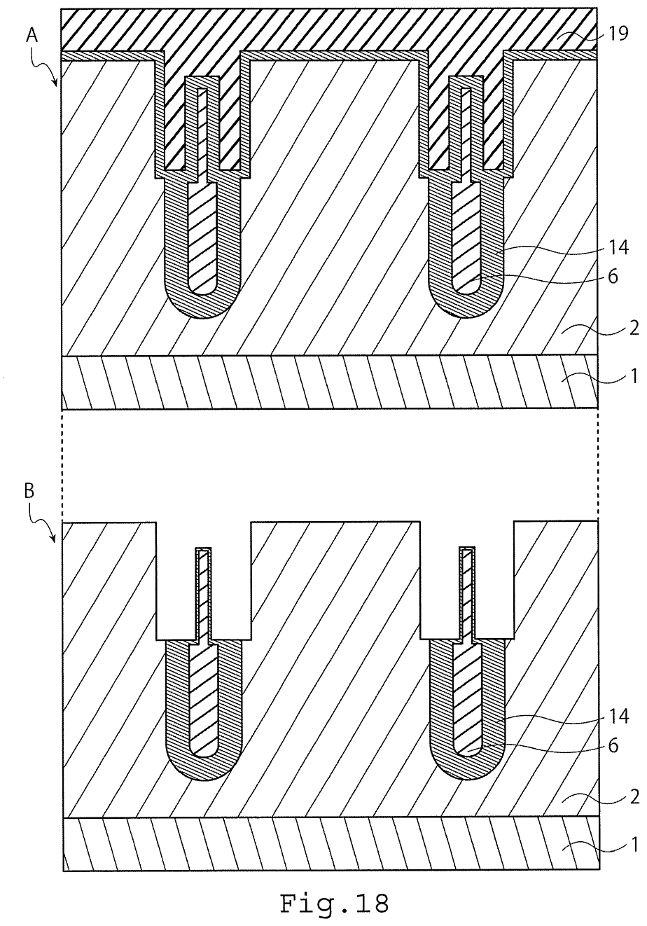

Then, the oxide film 14 of the member illustrated in the process diagram in FIG. 17 is etched to obtain a member illustrated in the process diagram in FIG. 18. In the first region A, the oxide film 14 is protected by the resist 19, and thus is not removed. However, the oxide film 14 in the second region B in which the resist 19 is not formed is removed. A portion of the insulating film 14 around the second portion being a thin portion of the field plate electrode 6 remains, but the entirety of the insulating film 14 around the second portion may be removed.

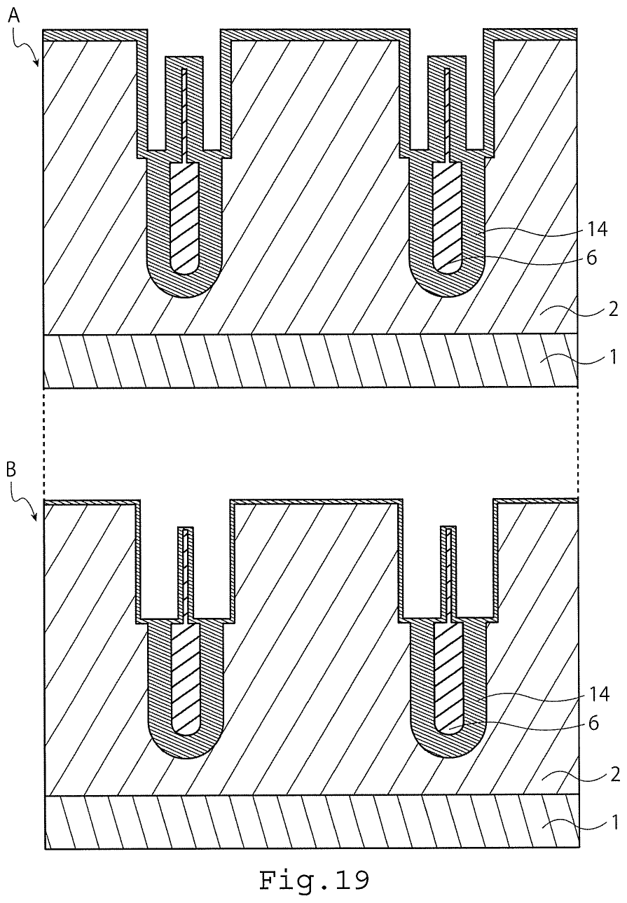

Then, the resist 19 of the member illustrated in the process diagram in FIG. 18 is removed. An oxidation treatment is performed to oxidize the exposed surface of the drift layer 2 in the second region B, and thus the insulating film 14 as the gate insulating film 10 is formed. In this manner, a member illustrated in the process diagram in FIG. 19 is obtained. Since the resist 19 is removed, and then the oxidation treatment is performed, it is possible to make the thickness of the oxide film 14 on the first region A side thicker. It is possible to make the poly oxide film 9 thicker by performing an oxidation treatment until the thin second portion of the field plate electrode 6 is totally removed.

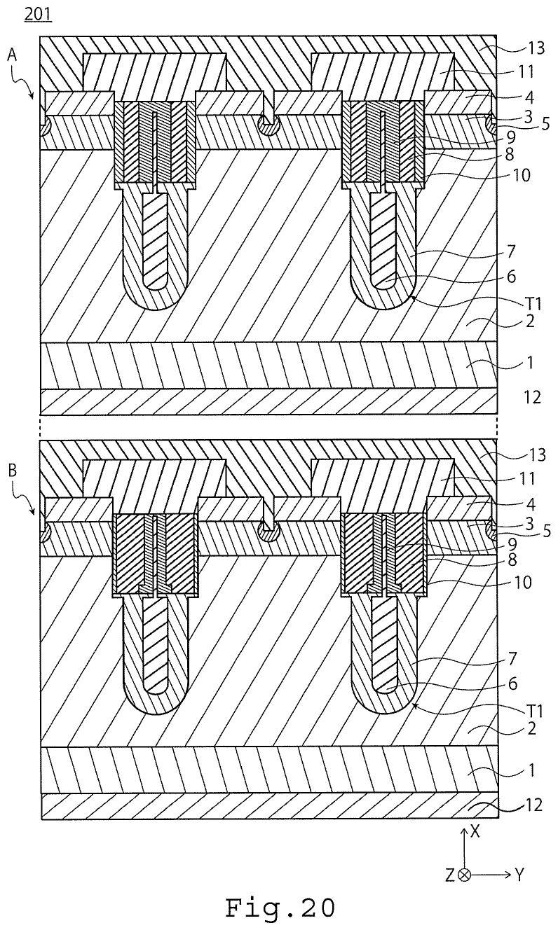

Then, it is possible to obtain the semiconductor device 200 by forming the gate electrode 8 and the like with the method illustrated in the process diagrams in FIGS. 10 to 13. In the second embodiment, processes illustrated in the process diagrams in FIGS. 7 to 9 are adopted, and thus it is possible to obtain the semiconductor device in which the gate electrode 8 has been cut out, as in a semiconductor device 201 illustrated in FIG. 20. If the resist 19 is formed, and then the processes illustrated in the process diagrams in FIGS. 7 to 9 are adopted, the gate electrode 8 in the second region B is cut out. It is possible to obtain a shape in which the gate electrode 8 in the first region A and the gate electrode B in the second region B are cut out, by adopting the processes illustrated in the process diagrams in FIGS. 7 to 9 before the resist 19 is formed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first semiconductor layer having a first conductive type;
a second semiconductor layer having the first conductive type and being provided on the first semiconductor layer;
a third semiconductor layer having a second conductive type and being provided on the second semiconductor layer;
a fourth semiconductor layer having the first conductive type and being provided on the third semiconductor layer;
a field plate electrode provided in a trench via a first insulating film, the trench provided in the second semiconductor layer, the third semiconductor layer, and the fourth semiconductor layer;
a first electrode provided in the trench to face the third semiconductor layer via a third insulating film; and
a second insulating film provided in the trench to be interposed by the first electrodes and having a first portion, the first portion being interposed by lower ends of the first electrodes and having a width wider than a width of a second portion interposed by centers of the first electrodes.

2. The device according to claim 1,
wherein the width of the first portion of the second insulating film is equal to or more than 1.10 times and equal to or less than 3.00 times the width of the second portion of the second insulating film.

3. The device according to claim 1,
wherein the width of the first portion of the second insulating film is equal to or more than 1.20 times and equal to or less than 3.00 times the width of the second portion of the second insulating film.

4. The device according to claim 1,
wherein a notch is provided at the lower end of the first electrode.

5. The device according to claim 1,
wherein a notch is provided at the lower end of the first electrode, and
the lower end of the first electrode protrudes toward the field plate electrode.

6. A semiconductor device comprising:
a first semiconductor layer having a first conductive type;
a second semiconductor layer having the first conductive type and being provided on the first semiconductor layer;
a third semiconductor layer having a second conductive type and being provided on the second semiconductor layer;
a fourth semiconductor layer having the first conductive type and being provided on the third semiconductor layer;
a first field plate electrode being provided in a trench via a first insulating film to be located on the first semiconductor layer side in a trench provided in the second semiconductor layer, the third semiconductor layer, and the fourth semiconductor layer and having a bottom located in the second semiconductor layer;
a first electrode provided in the trench to face the third semiconductor layer via a third insulating film; and
a second insulating film provided in the trench to be interposed by the first electrodes,
wherein a thickness of the third insulating film differs in a longitudinal direction of the trench.

7. The device according to claim 6,
wherein a region in which the third insulating film is thick in a longitudinal direction of the trench and a region in which the third insulating film is thin in the longitudinal direction of the trench are regularly arranged.

8. The device according to claim 6,
wherein a thickness of the third insulating film in a region in which the third insulating film is thick is equal to or more than two times and equal to or less than ten times a thickness of the third insulating film in a region in which the third insulating film is thin.

9. The device according to claim 6,
wherein a length of the trench in the longitudinal direction in a region in which the third insulating film is thick is equal to or less than two times a thickness of the second semiconductor layer in a first direction.

10. The device according to claim 6,
wherein a length of the trench in the longitudinal direction in a region in which the third insulating film is thick is equal to or more than 0.5 times and equal to or less than 2.0 times the length of the trench in the longitudinal direction in a region in which the third insulating film is thin.

11. The device according to claim 6,
wherein a thickness of the second insulating film in a region in which the third insulating film is thick is thicker than a thickness of the second insulating film in a region in which the third insulating film is thin.

12. The device according to claim 6,
wherein a thickness of the second insulating film in a region in which the third insulating film is thick is equal to or more than 1.5 times and equal to or less than 4.0 times a thickness of the second insulating film in a region in which the third insulating film is thin.

13. The device according to claim 6,
wherein a notch is provided at a lower end of the first electrode in a region in which the third insulating film is thin.

14. The device according to claim 6,
wherein a notch is provided at a lower end of the first electrode in a region in which the third insulating film is thin, and
the lower end of the first electrode protrudes toward the field plate electrode.

15. The device according to claim 6,
wherein a region in which the third insulating film is thick in a longitudinal direction of the trench and a region in which the third insulating film is thin in the longitudinal direction of the trench are alternately and regularly arranged.
